(19) United States
(12) Patent Application Publication
(10) Pub. No.: US 2026/0208744 A1
(43) Pub. Date: Jul. 23, 2026

(54) METHOD AND APPARATUS FOR UPDATING DYNAMIC DATA AND STATIC DATA

(71) Applicants: Hyundai Motor Company, Seoul (KR); Kia Corporation, Seoul (KR); HYUNDAI AUTOEVER Corp., Seoul (KR)

(72) Inventors: Chang Hun Jung, Incheon (KR); Seung Wook Park, Yongin-Si (KR); Jun Sung Yang, Seoul (KR); Jun Min Yi, Anyang-Si (KR)

(21) Appl. No.: 19/035,496

(22) Filed: Jan. 23, 2025

(30) Foreign Application Priority Data
Dec. 1, 2023 (KR) 10-2023-0172210

(51) Int. Cl. B60W 50/00; G01R 31/382

(52) U.S. Cl. CPC B60W 50/00; G01R 31/382; B60W 2050/0002; B60W 2556/45

(57) ABSTRACT

A method performed by an apparatus for controlling operation of a vehicle is introduced. The method may comprise receiving an update request, checking, based on the update request, a flying state of the vehicle and a battery charging state of the vehicle, updating, based on the flying state, the battery charging state, and data received via over-the-air (OTA), at least one of dynamic data or static data, wherein the dynamic data indicates a change in operational conditions of the vehicle, outputting, based on the updating the at least one of the dynamic data or the static data, a signal, and controlling, based on the signal, the operation of the vehicle.

### CROSS-REFERENCE TO RELATED APPLICATION

This application claims the benefit of priority to Korean Patent Application No. 10-2023-0172210, filed in the Korean Intellectual Property Office on Dec. 1, 2023, the entire contents of which are hereby incorporated herein by reference.

### TECHNICAL FIELD

The present disclosure relates to a method and apparatus for updating dynamic data and static data using Over-The-Air (OTA).

### BACKGROUND

The matters described in this Background section are only for the enhancement of understanding of the background of the disclosure, and should not be taken as acknowledgment that they correspond to prior art already known to those skilled in the art.

Urban Air Mobility (UAM) is a future city traffic system utilizing the sky as a moving path. The UAM may use a frequent update of data (such as static data or real-time data) on a situation change to assist safe flying, and an amount of data used may be huge. When a lot of data is updated all at once every time, it may be impractical to fly at a desired point in time due to lack of energy necessary for flying or energy charging. In addition, it may be difficult to ensure flying with updated information when a designation is changed while flying, or a flying distance may be shortened.

Accordingly, a way of updating data efficiently according to the type of energy or data before and during flight by utilizing an OTA technique is proposed.

### SUMMARY

According to the present disclosure, a method performed by an apparatus for controlling operation of a vehicle, the method may comprise, receiving an update request, checking, based on the update request, a flying state of the vehicle and a battery charging state of the vehicle, updating, based on the flying state, the battery charging state, and data received via over-the-air (OTA), at least one of dynamic data or static data, wherein the dynamic data indicates a change in operational conditions of the vehicle, outputting, based on the updating the at least one of the dynamic data or the static data, a signal, and controlling, based on the signal, the operation of the vehicle.

The method, wherein the updating the at least one of the dynamic data or the static data may comprise, based on the flying state corresponding to a pre-flight state and the battery charging state indicating an energy level of a battery of the vehicle being above a threshold level, updating the dynamic data and the static data, wherein the pre-flight state represents the vehicle receiving a request for flight but not yet deployed.

The method, wherein the updating the at least one of the dynamic data or the static data may comprise executing, based on a failure of the updating, a recovery mode, wherein the failure corresponds to updated data overlapping, conflicting, or colliding with existing data, and wherein the recovery mode corresponds to an operation of rechecking an update.

The method, wherein the updating the at least one of the dynamic data or the static data may further comprise, based on the flying state corresponding to an in-flight state and the battery charging state indicating the energy level of the battery being above the threshold level, updating the dynamic data, wherein the in-flight state represents the vehicle being airborne or actively flying.

The method may further comprise, based on the flying state corresponding to an in-flight state and the battery charging state indicating the energy level of the battery being below the threshold level, determining whether the battery is in a state capable of using a selective update mode, determining, based on a determination that the battery is in the state capable of using the selective update mode, a priority of data to update, and selectively updating, based on the determined priority of data, the dynamic data.

The method, wherein the determining the priority of data may comprise determining the priority of data to update such that a maximum flying distance is ensured based on the flying state of the vehicle.

The method may further comprise, based on the battery being in a state not capable of using the selective update mode, guiding the vehicle to an alternative landing point.

The method, wherein the selective updating the dynamic data may comprise, determining a failure of the updating the at least one of the dynamic data or the static data, wherein the failure is associated with data consistency between updated data and existing data, and based on the determining the failure, re-executing an update process of the at least one of the dynamic data or the static data.

The method may further comprise determining the battery charging state by comparing energy currently available in the vehicle with a sum of, energy required for the vehicle to fly from a current location of the vehicle to a destination, energy required for the vehicle to perform the updating, and system energy required for the vehicle to perform system operations during the fly from the current location to the destination.

The method may further comprise, updating the static data in a read only memory (ROM) and a random access memory (RAM), and updating the dynamic data in the RAM and a non-volatile memory (NVM).

According to the present disclosure, an apparatus for controlling operation of a vehicle, the apparatus may comprise, a processor, and a memory may comprise an instruction that, when executed by the processor, is configured to cause the apparatus to, receive an update request, check, based on the update request, a flying state of the vehicle and a battery charging state of the vehicle, update, based on the flying state, the battery charging state, and data received via over-the-air (OTA), at least one of dynamic data or static data, wherein the dynamic data indicates a change in operational conditions of the vehicle, output, based on the updated at least one of the dynamic data or the static data, a signal, and control, based on the signal, the operation of the vehicle.

The apparatus, wherein the instruction, when executed by the processor, is configured to cause the apparatus to, based on the flying state corresponding to a pre-flight state and the battery charging state indicating an energy level of a battery of the vehicle being above a threshold level, update the dynamic data and the static data, wherein the pre-flight state represents the vehicle receiving a request for flight but not yet deployed.

The apparatus, wherein the instruction, when executed by the processor, is configured to cause the apparatus to, based on a failure of the update, execute a recovery mode, wherein the failure corresponds to updated data overlapping, conflicting, or colliding with existing data, and wherein the recovery mode corresponds to an operation of rechecking an update.

The apparatus, wherein the instruction, when executed by the processor, is further configured to cause the apparatus to update, based on the flying state corresponding to an in-flight state and the battery charging state indicating the energy level of the battery being above the threshold level, the dynamic data, wherein the in-flight state represents the vehicle being airborne or actively flying.

The apparatus, wherein the instruction, when executed by the processor, is configured to cause the apparatus to, based on the flying state corresponding to an in-flight state and the battery charging state indicating the energy level of the battery being below the threshold level, determine whether the battery is in a state capable of using a selective update mode, determine, based on the battery being in the state capable of using the selective update mode, a priority of data to update, and selectively update, based on the determined priority of data, the dynamic data.

The apparatus, wherein the instruction, when executed by the processor, is configured to cause the apparatus to, based on the battery being in a state not capable of using the selective update mode, guide the vehicle to an alternative landing point.

The apparatus, wherein the instruction, when executed by the processor, is configured to cause the apparatus to, determine a failure to update the at least one of the dynamic data or the static data, wherein the failure is associated with data consistency between updated data and existing data, and based on the determined failure, re-execute an update process of the at least one of the dynamic data or the static data.

The apparatus, wherein the instruction, when executed by the processor, is configured to cause the apparatus to determine the battery charging state by comparing energy currently available in the vehicle with a sum of, energy required for the vehicle to fly from a current location of the vehicle to a destination, energy required for the vehicle to update the at least one of the dynamic data or the static data, and system energy required for the vehicle to perform system operations during the fly from the current location to the destination.

The apparatus, wherein the instruction, when executed by the processor, is configured to cause the apparatus to, update the static data in a read only memory (ROM) and a random access memory (RAM), and update the dynamic data in the RAM and a non-volatile memory (NVM).

According to the present disclosure, an apparatus for controlling operation of a vehicle, the apparatus may comprise, a processor, and a memory may comprise an instruction that, when executed by the processor, is configured to cause the apparatus to, identify an update event indicating an update of first data and second data is available, determine, based on the identified update event, a flying state of the vehicle and a battery charging state of the vehicle, update, based on the flying state, the battery charging state, and a type of the first data corresponding to a first data type, the first data with third data received via over-the-air (OTA), suspend, based on the flying state, the battery charging state, and the type of the second data corresponding to a second data type, update of the second data until a change of at least one of the flying state or the battery charging state, and control, based on the updating of the first data with the third data, the operation of the vehicle.

### BRIEF DESCRIPTION OF THE DRAWINGS

FIG. 1 shows an example of a vehicle connected to a server through a network.

FIG. 2 shows an example of functional blocks that make up a vehicle connected to an external network.

FIG. 3 shows an example of functional blocks that make up a gateway.

FIG. 4 shows an example of a function performed by a CCU.

FIG. 5 shows an example of functional blocks that make up a server.

FIG. 6 shows an example of an OTA system according to an example of the present disclosure.

FIG. 7 shows an example of detailed configurations of an SUMS and an OTAMS in an OTA system according to an example of the present disclosure.

FIG. 8 shows an example of an operation of an OTA update system according to an example of the present disclosure.

FIG. 9 and FIG. 10 show an example of a method for updating dynamic data and static data using OTA in an OTA update system according to an example of the present disclosure.

FIG. 11 shows an exemplary computing device capable of being applied to an example of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various examples of the present disclosure(s), examples of which are illustrated in the accompanying drawings and described below. While the present disclosure(s) will be described in conjunction with examples of the present disclosure, it will be understood that the present description is not intended to limit the present disclosure(s) to those examples of the present disclosure. On the other hand, the present disclosure(s) is/are intended to cover not only the examples of the present disclosure, but also various alternatives, modifications, equivalents and other examples, which may be included within the spirit and scope of the present disclosure as defined by the appended claims.

Hereinafter, various examples of the present disclosure are described in detail with reference to the accompanying drawings. In the following description, like reference numerals refer to like elements even though the elements are shown in different drawings. Furthermore, in the following description of the examples, a detailed description of known functions and configurations incorporated therein have been omitted for clarity and for brevity. Furthermore, terms such as first, second, A, B, (a), (b) may be used to describe components of the present disclosure. These terms are intended only to distinguish one component from another, and the nature, sequence, or order of the components is not limited by the terms. Throughout the specification, whenever any part is said to “include” or “comprise” any component, it is meant to be inclusive of other components, not exclusive of other components, unless specifically stated to the contrary. Furthermore, terms such as “~part,” “module,” and the like in the specification refer to a unit that handles at least one function or operation, which may be implemented in hardware or software or a combination of hardware and software. When a controller, component, device, element, part, unit, module, or the like of the present disclosure is described as having a purpose or performing an operation, function, or the like, the controller, component, device, element, part, unit, or module should be considered herein as being “configured to” meet that purpose or perform that operation or function. Each controller, component, device, element, part, unit, module, and the like may separately embody or be included with a processor and a memory, such as a non-transitory computer readable media, as part of the apparatus, or implemented as circuit or circuitry.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

The following detailed description, together with the accompanying drawings, is intended to show examples of the present disclosure and is not intended to represent the only examples in which the present disclosure may be practiced.

According to the present disclosure, data updates for flying vehicles, such as Urban Air Mobility (UAM) aircraft may be performed using OTA technology such that a vehicle may operate safely and energy efficient manner. It may distinguish between static data (like maps, regulations, and past weather patterns) and dynamic data (like current weather, air traffic, or emergencies) and selectively update them based on the vehicle's flight status and battery level. Before or during a flight, a system may evaluate the energy required for both the flight and the data updates. If energy is sufficient, it may update all necessary data; otherwise, it may prioritize critical information like safety updates. By using efficient memory allocation and prioritization, the system may ensure seamless data management, enabling safe and energy-efficient operations of the vehicle even under limited condition (e.g., insufficient battery level).

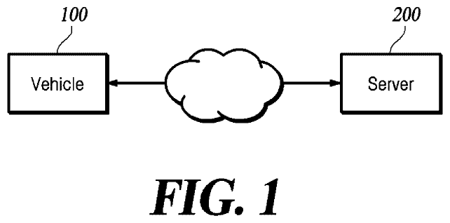

FIG. 1 shows an example of a vehicle connected to a server through a network.

A vehicle 100 may be connected to a server 200 which provides a function or service related to the vehicle 100 through a moving or wireless network such as LTE (Long Term Evolution), 5G (Generation), Wi-Fi, or the like.

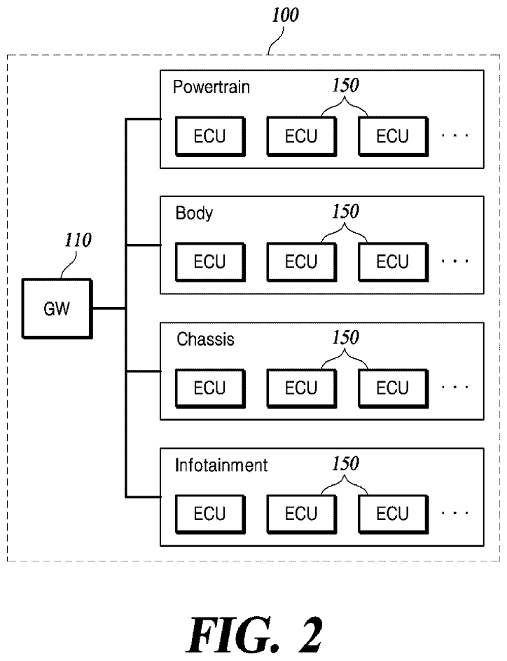

FIG. 2 shows an example of functional blocks that make up a vehicle connected to an external network.

The vehicle 100 may include a gateway (GW) 110 connected to an external network and an internal network, and subsystems connected to the internal network such as a powertrain subsystem, a body subsystem, chassis subsystem, and an infotainment subsystem.

The subsystem may connect components performing a similar function to an internal bus of the same type and include at least one electric component, and each electric component may be controlled and driven by an ECU 150.

The powertrain subsystem is a set of components to generate driving force for a vehicle, and may include components such as an engine, motor, transmission, battery, generator, or the like.

The body subsystem is a set of components for improving the convenience and safety of passengers, and may include components such as seats, heating, ventilating, and air conditioning (HVAC), lighting, doors, windows, indoor and outdoor lighting, or the like.

The chassis subsystem is a set of remaining components necessary for running an automobile except a body, and may include related components related, for example, to steering, braking, suspending, tire pressure measuring, or the like.

The infotainment subsystem is a set of components related to flying guidance or multimedia, and may include components such as a navigation, multimedia system, head-up display, or the like.

The internal network connecting the electric components that make up the gateway 110 and the subsystem may use a communication protocol such as a LIN (Local Interconnect Network), CAN (Controller Area Network), CAN-FD, FlexRay, MOST (Media Oriented Systems Transport), Ethernet, or the like.

The electric components of another subsystem using another communication protocol may exchange data with each other through the gateway 110.

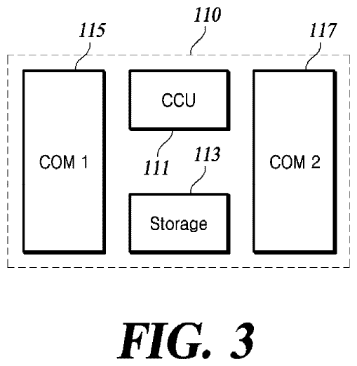

FIG. 3 shows an example of functional blocks that make up a gateway.

The gateway 110 may include a central control unit 111 for controlling the overall operation of a vehicle, a storage unit 113 for storing data received from the external and internal networks or data or information related to the operation of the vehicle, and an external transceiver (COM 1) 115 to be connected to the server 200 through the external network and an internal transceiver (COM 2) 117 to be connected to electric components (ECU) of the subsystem through the internal network.

The central control unit 111, the internal transceiver 117 and a separate storage unit may be separated from the gateway 110 and be made up of a separate apparatus.

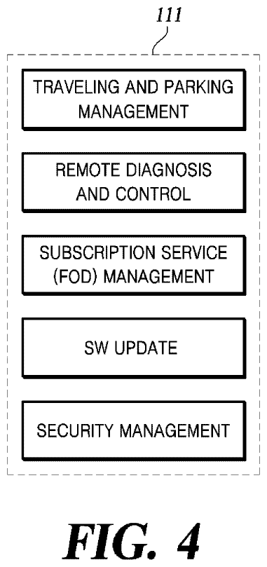

FIG. 4 shows an example of a function performed by a CCU.

The central control unit 111 may control the ECU 150 of at least one electric component included in at least one subsystem as needed upon request of a passenger or depending on a traveling situation and control various operations of the vehicle 100.

The function performed by the central control unit 111, in particular, the function performed based on data transmitted through the external network and/or the internal network may include traveling and parking management, remote diagnosis and control, subscription service (FOD) management, software renewal, security management, or the like.

The remote diagnosis and control is designed to transmit state information collected while a vehicle is flying to the server 200 and diagnose the same in real time, and change a control condition of a vehicle based on the diagnosis result received from the server or support remote control in case of emergency.

The subscription service (FOD) management is designed to manage FOD (Feature On Demand), a kind of subscription service, by downloading a new function through the server 200 or a client terminal for activation or activating a function that is already mounted but is deactivated for use.

The central control unit 111 may perform a setting or cancelling operation of the subscription service, check whether the service requested by a client is activated by choosing a subscription by the client or whether the subscription service is activated by an improper method, and may perform or may not perform the corresponding service based thereon.

The software renewal is a service performed by the central control unit 111 when a vehicle to which OTA is applied satisfies a software renewal condition, and may include renewal of software (an operation system of the central control unit 111) that manages the overall operation of a vehicle as well as renewal of firmware installed in the ECU 150 of each electric component.

The security management may include a function or service related to the security of a vehicle or the authentication of an accessing external device.

The security threat related to a vehicle may include firmware modulation, vehicle remote control hacking, forgery of CAN, vehicle illegal manipulation, denial of service, or the like. In addition, the security threat related to external network communication may include communication intercept, forgery of messages, or the like.

The security management may perform, for example, a function for detecting and responding to intrusions to the internal network of a vehicle through the external network (IDS: Intrusion Detection System), a record service of data related to a security event (data immediately before a security accident) (EDR: Event Data Recorder).

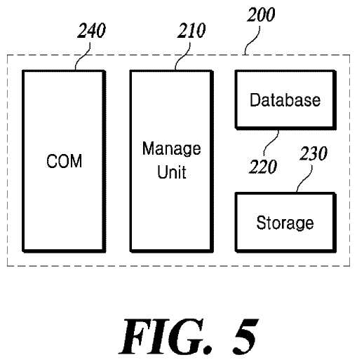

FIG. 5 shows an example of functional blocks that make up a server.

The server 200 may include: a management unit 210 for managing an operation according to the request of a vehicle such as renewal of software, transmission of data related to the FOD, security and authentication of the vehicle, or the like; database 220 for managing information related to each vehicle such as software version installed in each vehicle, activated subscription service, information related to authentication, or the like; a storage unit 230 for storing a software of various versions, data related to traveling of a plurality of vehicles, or the like; and a transceiver (COM) 240 which is connected to the vehicle 100 through the external network for exchanging data.

The server 200 may be divided depending on a function or service performed by the central control unit 111 of the vehicle 100 and may be configured in a plurality of different servers.

The database 220 may be separated from the server 200 for installation.

The content described in relation to FIGS. 1 to 5 is related to a vehicle, and may be applied to the vehicle as well as UAM. Hereinafter, the vehicle and UAM may be described as an “apparatus.”

The static data (fixed data) according to an example of the present disclosure may provide basic data necessary for complying with the planning and regulations, and may be shown as in Table 1 as an example, without being limited thereto.

TABLE 1
\textcircled{1} Infrastructure: Fixed physical element information such as taking off
and landing site (vertiport), charging station, airspace path, or the like
\textcircled{2} Regulations and policies: Regulation and policy information for
managing UAM operation of a specific area or country
\textcircled{3} Geographical-spatial information: Spatial information such as maps,
geographic information, building height, or the like
\textcircled{4} Weather and environment: Weather conditions may be changed, but
static weather and environment data contains information on past
weather patterns, climate data, and issues related to weather
known in an area.
\textcircled{5} Population and population statistics: Information on population
density of an urban area, traffic habits, and demographic characteristics
(helpful in demand modeling and route optimization)
\textcircled{6} Legal and insurance data: Information on insurance requirements
and responsibilities of a UAM operator (which may vary depending
on areas and affect a business plan)
\textcircled{7} All pieces of data in the case where energy is sufficient
\textcircled{8} Data that needs to be maintained when power is off or on

The dynamic data (real-time data) according to an example of the present disclosure may be shown as in Table 2, without being limited thereto. The operator and regulation authority may utilize dynamic information to be adapted to the changing conditions, and may continuously ensure the safety and function of a UAM ecosystem.

TABLE 2
\textcircled{1} Real-time weather data: Unlike static weather data, dynamic weather
information contains a current weather state, forecast, and a warning
after bad weather (real-time determination for a flight route and safety).
\textcircled{2} Air traffic and vehicle moving data: Real-time data information on
the movement of another aircraft including a UAM vehicle and general
aircrafts in airspace (important information for preventing collision
and managing traffic)
\textcircled{3} Passenger demand: Information on current and prospective
passenger demand for an UAM service (flight schedule and pricing
optimization)
\textcircled{4} Emergency: Dynamic information on a site and cause of
accident and a state of a nearby UAM vehicle in case of emergency
or accident (a countermeasure and safety action)
\textcircled{5} Maintenance and vehicle state: Real-time data for a maintenance
state and a state of a vehicle as for an UAM operator (ensuring a
safe and stable operation and including diagnosis system data
and a sensor of an aircraft)
\textcircled{6} Airspace management: Real-time updated information on an
airspace limit, temporal restricted airspace, and traffic congestion
of urban airspace
\textcircled{7} Data that does not need to be maintained after power is off or on

A storage memory according to an example of the present disclosure may be changed according to the static and dynamic data characteristics. The static data may be updated in a read only memory (ROM) (e.g., erasable programmable ROM (EPROM), electrically erasable programmable ROM (EEPROM), Flash Memory, etc.), and the dynamic data may be updated in a random access memory (RAM).

When power is off, the information needed to be stored (static data) may be updated in the ROM. For example, in the case of the data that does not change in real time such as maps, geographical features, buildings, charging stations, or the like, or in the case where the size of updated data is large, an update is performed in the ROM before taking-off (flying).

The information that does not need to be maintained when power is off or on (dynamic data) is updated in the RAM. For example, in the case of the data that changes in real time such as real-time weather, traffic, emergency information, or the like, or in the case where the size of data that is helpful in a flying path is small, an update is performed during flight. In the case of the dynamic data that needs to be maintained even after the power is off or on, the data may be maintained by using a non-volatile memory (NVM).

If sufficient energy (battery) is retained or chargeable before the UAM takes off (flies), update constraints do not occur. However, if data is frequently updated or a large amount of data is updated while the UAM is flying, the update constraints occur due to energy consumed for data transmission and reception and energy consumed for flight.

In addition, if a route change is unavoidable due to deteriorating weather conditions (or a motor output change), emergency/unexpected situations, or the like, baggage is overloaded, and a destination is changed, normal flying may be impossible due to lack of retentive energy (battery).

In this connection, if there is sufficient energy during flight, all pieces of dynamic data are updated. In contrast, if there is no sufficient energy during flight, data is updated selectively according to the importance of data (e.g., a selective update mode).

To improve the efficiency of data updates and ensure safe operation of a vehicle, the selective update mode may be used when energy sufficiency is limited. In this mode, a system may prioritize updates based on predefined or user-defined requirements, such as increasing or maximizing the operational range, ensuring the fastest arrival at the destination, responding to emergencies, or conserving energy. For example, when maximizing range, the system may prioritize updates that impact navigation and energy optimization (e.g., real-time weather updates, and route adjustments, etc.) to ensure the vehicle reaches its destination efficiently. For the fastest arrival, updates related to traffic or airspace conditions (e.g., live air traffic updates or temporary flight restrictions, etc.) are prioritized to calculate the quickest route. During emergency response scenarios, the system may focus on updates on, for example, emergency zones, passenger needs, or nearby hazards to ensure the emergency response scenarios is handled safely and effectively. In case of low energy levels, the system may conserve resources by limiting updates to safety-critical data, such as immediate weather hazards or communication with control systems, to preserve battery life for essential operations. This prioritization is achieved through a dynamic ranking mechanism that considers operational context, user preferences, and energy constraints. By prioritizing the more or most relevant data update, the selective update mode may ensure that the vehicle remains operational and maintain safety while enhancing battery usages.

In another additional example, the importance of data may be considered depending on the center (weight) of baggage, the center of maximum distance, and the center of maximum speed. When a user selection mode is selected according to the importance of data, a flying distance is measured.

In another additional example, an update may be performed by applying an update item priority in order to ensure the destination longest distance based on a current state. For example, in case of urgent patient transportation, the priority is as shown in Table 3, without being limited thereto.

TABLE 3
Real-time weather and traffic data > Emergency > Passenger Demand

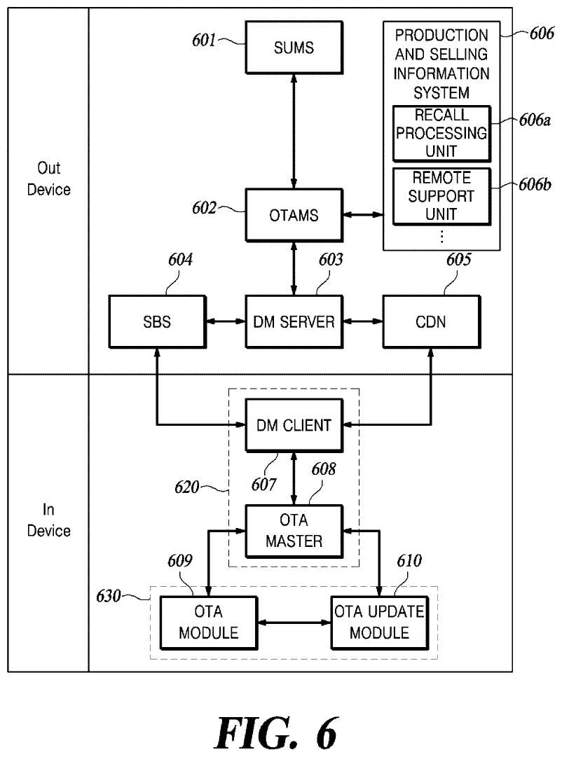

FIG. 6 shows an example of an OTA system according to an example of the present disclosure.

The OTA system may be divided into Out-Device and In-Device.

The Out-Device (for example, a UAM, a vehicle, or the like) refers to a system for an OTA service in an external environment, manages software update and integrally manages deployment, control and service, guides (expresses) a user about update influence, and manages update and state of a device.

The Out-Device includes a software update management system (SUMS) 601, an OTA management system (OTAMS) 602, a device management (DM) server 603, a service bus system (SBS) 604, a contents delivery network (CDN) 605, and/or a production and selling information system 606.

The DM server 603 operates based on an open mobile alliance-device management (OMA-DM) regulation, and may refer to a server that communicates with a management controller for managing and controlling various devices at the center.

The OTAMS 602 is the OTA management system, and performs a role of the overall control and OTA update deployment current situation.

The CDN 605 refers to a server for deploying ROM Data.

The production and selling information system 606 includes a recall processing unit 606a and a remote support unit 606b.

When the UAM is defective, the recall processing unit 606a manages a whitelist and blacklist as a recall service system for retrieving or modifying the UAM or a campaign service system for marketing or information delivery. Herein, the whitelist refers to a list of reliable items, and the blacklist refers to a list of unreliable or prohibited items.

The remote support unit 606b diagnoses and solves technical issues or errors that may occur during an update process remotely.

A package is delivered from the SUMS 601 in charge of SW package registration, SW release, or the like to the OTAMS 602 which manages OTA deployment. The SUMS 601 and the OTAMS 602 update SW release period, update deployment schedule, version management, update state monitoring and user experience.

The OTAMS 602, which is an OTA update deployment current situation overall control system, collects information of an apparatus (a software update, an update process, or the like) through the DM server 603, manages the apparatus, and adjust an update process. In addition, the OTAMS 602 tracks the state of an apparatus and a software version and requests a specific apparatus or group to update the OTA if necessary.

The DM server 603 may efficiently deliver newly updated ROM data to an apparatus through the CDN 605. The DM server 603 may deliver the ROM data quickly through the CDN 605 and may operate an update process more efficiently.

In addition, the DM server 603 performs apparatus registration and management, message relay, update and configuration management, safe communication, and real-time event monitoring through the SBS 604 in order to operate the system efficiently.

The In-Device includes a DM client 607, an OTA master management control unit 608, an OTA module 609, and an OTA update module 610.

Herein, a CCU (or a DCU (Domain Control Unit)) 620 includes the DM client 607 and the OTA master management control unit 608.

A performance controller 630 updates the OTA, and includes the OTA module 609 and the OTA update module 610.

The DM client 607 is a module that operates based on the OMA-DM regulation, and plays roles of requesting a software or firmware update necessary for communication with the DM server 603 wirelessly and performing the same.

The DM client 607 fulfills a download request through the CDN 605, and maintains the data of an apparatus to be up-to-date by adjusting the update timing in conjunction with the CDN 605.

The DM client 607 and the SBS 604 help to balance the management and communication of an apparatus client, and increase the system stability and reliability by performing the management, update, state monitoring and event processing of an apparatus.

The DM client 607 receives the ROM data from the Out-Device and performs update and management of apparatuses in the In-Device through the OTA master management control unit (hereinafter referred to as “OTA master”) 608 based on the received data. The OTA master 608 prepares to update the OTA of each device module that makes up the entire system.

The OTA master 608 and the OTA module 609 check the information (for example, current ROM version, successful update, update failure, or the like) of the system of the In-Device (UAM, AAM, Vehicle, or the like) through communication therebetween.

The OTA module 609 and the OTA update module 610 manages the current controller state information requested by the management and the request of the Out-Device through communication with the OTA master 608. Herein, the current controller state information includes the working state information of a performance controller.

The OTA update module 610 updates software or firmware remotely by using an OTA technique through a wireless communication method. More specifically, the OTA update module 610 communicates with the OTA master 608 in order to update a performance controller 630. In other words, the OTA update module 610 performs an OTA module update through the update information received from the OTA master 608. The OTA update module 610 processes data for the update information, not general information.

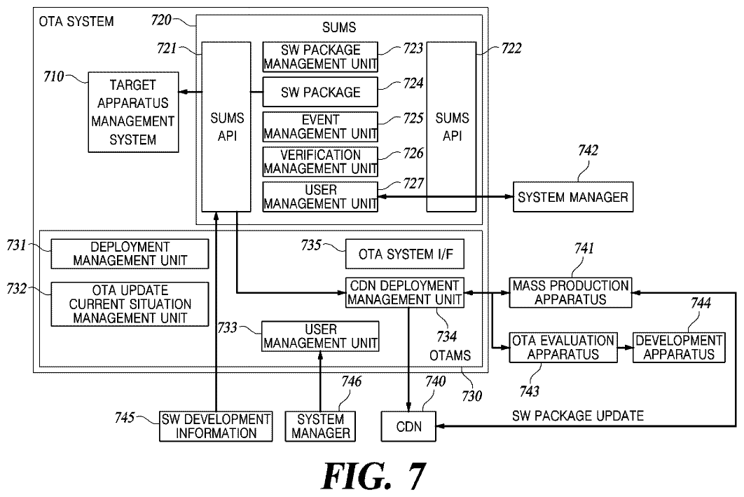

FIG. 7 shows an example of detailed configurations of an SUMS and an OTAMS in an OTA system according to an example of the present disclosure.

The OTA system includes a target apparatus management system 710, an SUMS 720, and an OTAMS 730. System managers 742 and 746 may manage users in the SUMS 720 and the OTAMS 730, and may display the influence of the approved SW and SW update to the users (drivers).

The target apparatus management system 710 manages a list of target apparatuses to be updated and manages an apparatus update history. The list of target apparatuses to be updated may be priority information of target apparatuses to be updated.

The SUMS 720 is in charge of managing the entire SW including SW package deployment verification, event, and SW package, and manages a list of updated apparatuses and an update history through connection management of the SW package.

The SUMS 720 includes an SUMS application programming interface (API) 721, an SUMS API 722, a SW package management unit 723, a SW package 724, an event management unit 725, a verification management unit 726, and a user management unit 727.

The SUMS API 721 and the SUMS API 722 refer to interfaces that provide various functions related to software update management for an external application or service to utilize. The SUMS API 721 and the SUMS API 722 refer, for example, to interfaces provided to receive SW development information from the outside. The SUMS API 721 receives SW development information 745 used in the SUMS 720. The SW development information 745 includes SW package information and SW package specifications.

The SW package management unit 723 checks a list of target apparatuses to be updated through communication with the target apparatus management system 710, and manages an update history. In addition, the SW package management unit 723 may manage an updated SW package. In addition, the SW package management unit 723 may perform package or SW package connection management through the target apparatus management system 710.

The SW package 724 stores the updated SW package.

The event management unit 725 manages an event such as a development content update, SW freeze, and mass production update.

The verification management unit 726 performs SW package deployment verification management.

The user management unit 727 manages the authority and history of a user in the SUMS 720, and helps the system manger 742 to manage the authority and history of the user in the SUMS 720.

The OTAMS 730 is a system that deploys and manages the SW package managed through the SUMS 720 to an apparatus, and manages an OTA update current situation (for example, an updated quantity, an update progress current situation, update error management, or the like).

The OTAMS 730 includes a deployment management unit 731, an OTA update current situation management unit 732, a user management unit 733, a CDN deployment management unit 734, and an OTA system I/F 735.

The deployment management unit 731 manages SW package OTA deployment.

The OTA update current situation management unit 732 manages an OTA update current situation. In other words, the OTA update current situation management unit 732 manages OTA updated quantities, OTA update progress situations, and OTA update errors.

The user management unit 733 manages the authority and history of a user in the OTAMS 730, and helps the system manger 746 to manage the authority and history of the user in the OTAMS 730.

The CDN deployment management unit 734 performs SW package uploading and CDN folder management and history management for apparatus deployment, and delivers the corresponding SW package to an OTA evaluation apparatus 743 for a development apparatus 744 to update.

The OTA system IF 735 refers to an interface for data transmission and reception between an external server and each module in the OTAMS.

The CDN 740 refers to a server for deploying ROM Data, and communicates with the CDN deployment management unit 734 to update the SW package in a mass production apparatus 741.

The mass production apparatus 741 may download a SW package after checking up-to-date SW through the CDN deployment management unit 734. The mass production apparatus 741 may check the up-to-date SW, and then download the SW package in the case where the structure of the SW package is different from that of a previous SW package.

The OTA evaluation apparatus 743 manages an OTA update log after checking the up-to-date SW through the CDN deployment management unit 734, and informs the development apparatus 744 of an OTA evaluation result after evaluating development OTA. The reliability of the apparatus may be ensured through the OTA evaluation apparatus 743.

The development apparatus 744 uses the OTA evaluated through the OTA evaluation apparatus 743 to update the SW package.

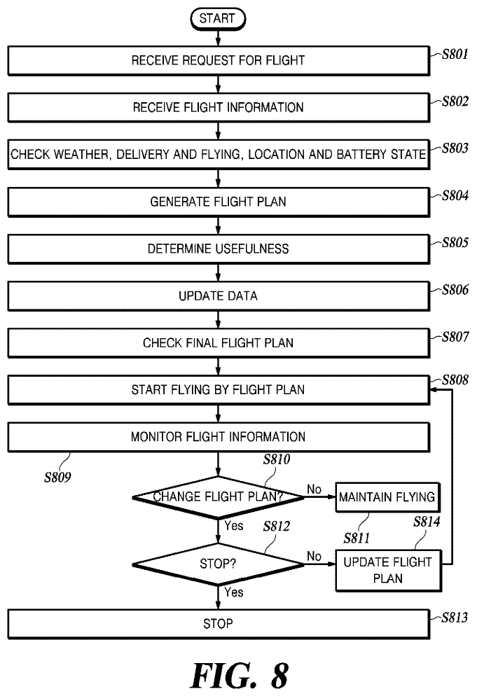

FIG. 8 shows an example of an operation of an OTA update system according to an example of the present disclosure.

The OTA update system is broadly classified into a pre-flight state, a state during deployment, and a state during flight according to the state of an apparatus. During the pre-flight state, the vehicle is stationary, and updates may be performed with least energy constraints. At this state, all static data (e.g., geographical maps, infrastructure details, or regulations, etc.) may be updated to ensure compliance and preparedness. If sufficient battery energy is available, dynamic data (e.g., real-time weather forecasts, air traffic conditions, etc.) may be also updated to enhance operational readiness. The completeness of updates may be prioritized since energy constraints are less critical in the pre-flight state.

The pre-flight state refers to a state in which an aircraft has received a request for flight before flight but has not yet been deployed on the runway.

The state during deployment (e.g., a deployment state) refers to a state in which an aircraft gets ready to fly before flight after the pre-flight state and before taking-off. In other words, the deployment state refers to a state in which an aircraft is not being supplied or charged with energy before taking-off and is deployed (e.g., positioned for takeoff but not yet airborne) before taking off. In the deployment state, updates may be limited to critical real-time information required for immediate operational safety, such as emergency alerts or updated flight restrictions. In the deployment state, those updates that are essential for the initial flight phases may be prioritized.

The state during flight (e.g., an in-flight state) refers to a state in which an aircraft takes off after being deployed in the state during flight (e.g., airborne or actively flying). During the in-flight state, the vehicle's battery state and operational condition may be dynamically evaluated. Updates may be limited to the most critical dynamic data (e.g., live weather changes, air traffic data, or emergency notifications, etc.) to ensure the safe and efficient continuation of the flight. Decision-making at this state may be based on an energy sufficiency formula (see Equation 1 below), comparing remaining battery energy with the sum of energy required for flight, data updates, and system operations. This approach may ensure data updates do not compromise the flight's completion or safety. By tailoring the update process to these states, efficient data delivery may be ensured while maintaining operational safety and energy optimization.

Stages 801 to 806 refer to an operation of the pre-flight state, stage 807 refers to an operation of the state during deployment, and stages 808 to 814 refer to an operation of the state during flight.

The OTA update system may be understood as constituents 620, 630 of the In-Device of FIG. 6.

The OTA update system receives a request for flight in the pre-flight state in stage 801, and receives flight information in stage 802.

The OTA update system updates the static data such as an energy state of the current apparatus, a distance from the destination, weather in a flying route, regulations and policies on the move between regions, or the like in S803. The static data is shown in Table 1.

If there is energy sufficient enough to fly on a distance flight (a state in which energy is being supplied or charged or there is sufficient energy), all pieces of data including the static data may be updated.

The OTA update system establishes a flight plan using the information updated in stage 804.

The OTA update system determines a flying-related schedule and flying management information according to the state of an apparatus such as a flying distance, baggage weight, or the like during flight or delivery based on the flight plan established in stage 805.

The OTA update system modifies and updates the static data again based on the flight plan determined according to the state of an apparatus in stage 806. In this connection, the OTA update system modifies and updates data to the same condition state as the state in stage 803.

The OTA update system checks the final flight plan in the pre-flight state together with an apparatus state in the state during deployment in stage 807.

The OTA update system takes off and begins flying based on the finally decided flight plan in stage 808.

The OTA update system continuously monitors the dynamic data such as weather, emergency, an apparatus state, or the like during flight in stage 809. The dynamic data is shown in Table 2.

The OTA update system determines in stage 810 whether a monitoring result or a flight plan of an apparatus has changed.

If the flight plan of the apparatus has not been changed, the OTA update system maintains flying in stage 811.

In contrast, if the flight plan of the apparatus has been changed, the OTA update system 812 determines whether to stop flying in stage 812.

If it is determined to stop flying, the OTA update system stops flying in stage 813.

If it is not determined to stop flying, the OTA update system updates a flying plan in stage 814. If there is sufficient energy (a state in which energy is being supplied or charged or there is energy sufficient enough to fly on a distance flight), the OTA update system may update all pieces of data including the dynamic data. In addition, if the flight plan of an apparatus is changed, the OTA update system may ignore the updated information depending on energy or state of the apparatus. If flight information is not updated, an aircraft may be operated according to the previous flight plan.

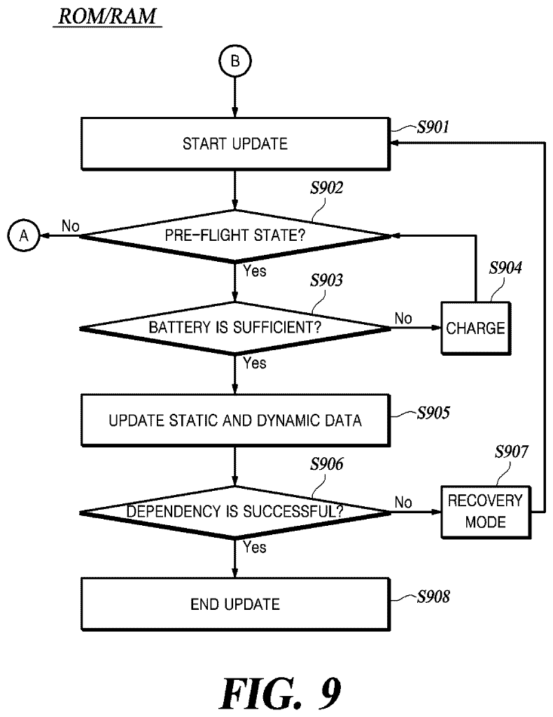

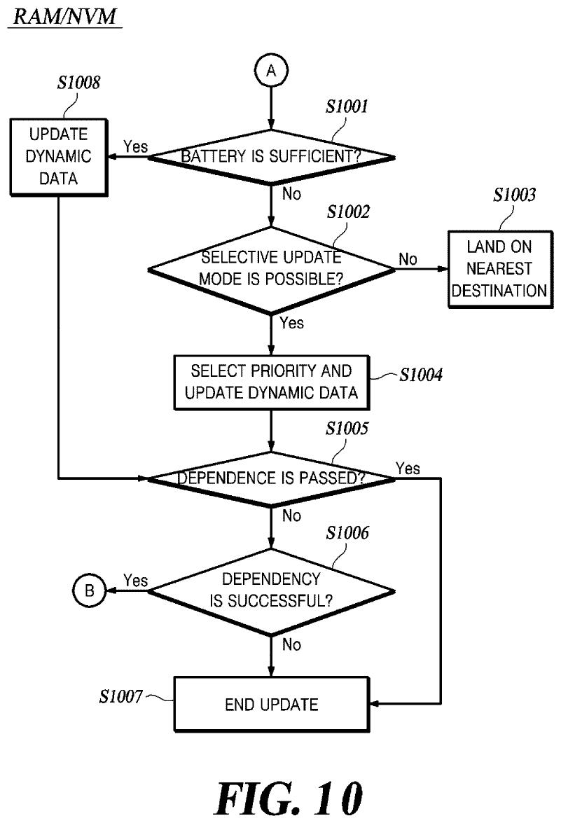

FIGS. 9 and 10 show an example of a method for updating dynamic data and static data using OTA in an OTA update system according to an example of the present disclosure.

A data update is stored by using different types of storage memories (volatile/non-volatile) depending on the type of data (static data/dynamic data) and data characteristics.

FIG. 9 is an operation flowchart illustrating an example of data stored in ROM or RAM. FIG. 10 is an operation flowchart illustrating an example of data stored in RAM or NVM.

The data that needs to be maintained if power is off-on is stored in a non-volatile memory area (ROM or NVM), and the data that does not need to be maintained after power off-on is stored in a volatile memory area (RAM). The data that needs to be maintained if power is off-on refers to static data, and the data that does not needs to be maintained refers to dynamic data.

According to the contents of data and exceptional situations designated by a user, the dynamic data may also be stored in a non-violate memory, if necessary.

FIGS. 9 and 10 show a process of updating data according to the energy state of an apparatus, the type of data, and the type of storage memories according to an example of the present disclosure.

The OTA update system starts an update in stage 901. If it is determined to start the update, the update is started according to a current update request and a flying state.

The OTA update system checks whether it is the pre-flight state in stage 902.

If it is not the pre-flight state, the OTA update system proceeds to

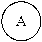

### of FIG. 10.

In contrast, if it is the pre-flight state, the OTA update system determines in stage 903 whether a battery state is sufficient.

A method of checking the battery state is as follows.

It is determined that a battery is sufficient if the sum of energy (Er) needed to fly (e.g., propulsion energy) from a current location until landing on a destination, energy (Eu) consumed for an update, and system energy(Es) (e.g., energy consumed by onboard systems necessary for flight, such as avionics, sensors, communication, or control systems, etc.) consumed from the current location until landing on the destination is less than the energy (Er) currently left in the apparatus. It is determined that the battery is insufficient in an opposite case. In other words, the sufficient battery state and the insufficient state may be determined based on Equation 1 below.

$$Sufficient battery state : {E}_{r} > {E}_{f} + {E}_{u} + {E}_{s} \qquad [ Equation 1 ]$$

$$Insufficient battery state : {E}_{r} \leq {E}_{f} + {E}_{u} + {E}_{s}$$

If the battery state is insufficient, the OTA update system is charged in stage 904, and then proceeds to stage 902. In other words, if the battery state is insufficient in the pre-flight state, the OTA update system does not update data but performs a charging request.

In contrast, if the battery state is sufficient, the OTA update system updates the static and dynamic data in stage 905. In other words, in the pre-flight state, if the energy of an apparatus is sufficient, the static and dynamic data is updated.

Thereafter, the OTA update system checks in stage 906 whether dependency (e.g., data consistency between new data A and existing data B) is successful. Herein, if the updated data overlaps or collides with the previous data, it is determined as “dependency failure” (e.g., new data A and existing data B are not consistent). If the updated data does not overlap or collide with the previous data, it is determined as “successful dependency.”

As a result of checking the dependency, in the case of dependency failure (e.g., an update failure during data or software updates), the OTA update system executes a recovery mode to recheck the update or maintains the operation in stage 907. The recovery mode works if a SW operation of a SW Normal area is stopped due to an error during an update period or a system shutdown. The recovery mode enters a system subregion by booting failure sensing or commands and is converted into a state that communication is available during a system reset or booting process. Thus, an external input may be received, an update may be rechecked to retry an update, and an operation may be maintained. In the case of the impossible situation of recovery due to the system reset, the SW may be installed by Boot SW reprogramming.

Specifically, if an update failure is detected, a system may transition into the recovery mode, which may comprise entering a fail-safe operational state to diagnose and resolve the issue. For example, if a dependency check fails due to conflicting or overlapping data, the system may initiate a rechecking process to identify and rectify the inconsistencies. In cases where the system encounters a software crash or unexpected power loss during an update, a booting fail-safe mode may be activated, allowing the vehicle's control system to reboot into a protected subregion with limited functionality, enabling safe communication and repair operations. Additionally, if critical software components are corrupted, the recovery mechanism may comprise reprogramming the affected regions using stored backup data or retrieving fresh updates from an external server via Over-The-Air (OTA) communication. For example, in scenarios where an emergency update (e.g., real-time weather data) fails during flight, the system may revert to previously stored stable data to maintain safe operations. Similarly, if a firmware update for the vehicle's control systems is interrupted, the recovery mode may ensure the system retains basic control functionality to safely land the vehicle. This recovery mechanism may prioritize operational safety and ensure the vehicle may resume normal updates or revert to its last stable state, minimizing disruption to operations of the vehicle.

As a result of checking the dependency, if the dependency is successful, the OTA update system ends the update in stage 908.

If stage 902 is the state during flight, not the pre-flight state, the OTA update system determines whether the battery is sufficient in stage 1001 of FIG. 10.

If the battery state of an apparatus is insufficient during flight, the OTA update system checks whether the battery state is capable of executing the selective update mode in stage 1002. If the battery is in a state not capable of executing the selective update mode, the OTA update system guides the apparatus to an alternative landing point (e.g., a nearest landing point) in stage 1003. In other words, if an arrival at a destination is prioritized in a current state because an additional flight plan is no longer modified or the arrival at the destination is not ensured due to an external phenomenon, the OTA update system controls the apparatus to be landed on a nearby safe place without a data update.

If the battery state is capable of executing the selective update mode, the OTA update system selects a priority in stage 1004 and updates the dynamic data in consideration of the selected priority. In other words, the OTA update system applies an flight plan according to user selection. The selective update mode may update only the information optimized for the requirements such as the maximum distance flight, the earliest arrival time, or the like.

Thereafter, the OTA update system checks the dependency is successful in stage 1005.

As a result of checking the dependency, in the case of dependency failure, the OTA update system determines whether to retry the update in stage 1006. In other words, as a result of checking the dependency according to the battery state of the current apparatus in the state of flying the apparatus, the OTA update system determines whether to retry the update for the failed SW.

If the update is retried, the OTA update system proceeds to

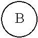

### of FIG. 9.

In contrast, if the update is not retried, the OTA update system ends the update in stage 1007.

As a result of checking the dependency in stage 1005, in the case of successful dependency, the OTA update system ends the update in stage 1007.

In stage 1001, if the battery is sufficient, the OTA update system updates the dynamic data. Thereafter, the OTA update system checks whether the dependency is successful in the state where the battery is sufficient in stage 1005. As a result of checking the dependency, in the case of dependency failure, the OTA update system determines whether to retry the update in stage 1006. In other words, as a result of checking the dependency in the case where the battery of the current apparatus is sufficient in the state of flying the apparatus, the OTA update system determines whether to retry the update for the failed SW.

If the update is retried, the OTA update system proceeds to

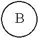

### of FIG. 9.

In contrast, if the update is not retried, the OTA update system ends the update in stage 1007.

As a result of checking the dependency in stage 1005, in the case of successful dependency, the OTA update system ends the update in stage 1007.

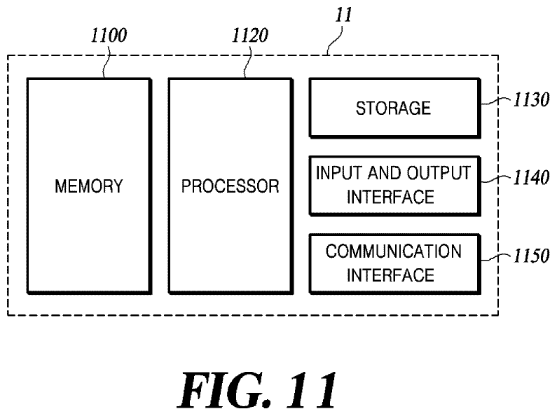

FIG. 11 shows an exemplary computing device capable of being applied to an example of the present disclosure.

Referring to FIG. 11, a computing device 11 may include all or part of a memory 1100, a processor 1120, storage 1130, an input and output interface 1140, and a communication interface 1150. The computing device 11 may include at least part of the OTA update system structurally and/or functionally. The computing device 11 may be a stationary computing device, such as a desktop computer, a server and/or an intelligent camera, as well as a mobile computing device, such as a smartphone and/or a laptop computer.

The memory 1100 may store a program that causes the processor 1120 to perform a method(s) according to an example of the present disclosure. For example, the program may include a plurality of instructions executable by the processor 1120, and the aforementioned OTA update system may be performed by executing the plurality of instructions by the processor 1120.

The memory 500 may be a single memory or a plurality of memories. In this connection, information required to perform the operation of the aforementioned OTA update system may be stored in a single memory or may be divided and stored in a plurality of memories. When the memory 1100 is configured of a plurality of memories, the plurality of memories may be physically separated. The memory 1100 may include at least one of a volatile memory and a non-volatile memory. The volatile memory may include a static random access memory (SRAM) or a dynamic random access memory (DRAM), and the non-volatile memory may include a flash memory, and the like.

The processor 1120 may include at least one core capable of executing at least one instruction. The processor 1120 may be a single processor or a plurality of processors. The processor 1120 may execute instructions stored in the memory 1100.

For example, the processor 1120 executes the instructions stored in the memory 1100 to receive an update request, check a flying state of an apparatus and a battery charging state of the apparatus, and update the dynamic data and static data in consideration of the flying state and the battery charging state.

The storage 1130 maintains stored data even if power supplied to the computing device 11 is cut off. For example, the storage 1130 may include non-volatile memory, and may include storage media such as magnetic tape, optical disk, or magnetic disk.

The storage 1130 may store data to be processed by the processor 1120 and data processed by the processor 1120. The program or data stored in the storage 1130 may be loaded into the memory 1100 before being executed by the processor 1120. The storage 1130 may store a file written in a program language, and a program generated from the file by a compiler or the like may be loaded into the memory 1100.

The input and output interface 1140 may provide an interface with an external device for data input and output. The computing device 11 may acquire an electronic signature through the input and output interface 1140. The input and output interface 1140 may provide an interface with an input device such as a keyboard, a mouse, or a touch interface, and an output device such as a display device, or the like. A user may trigger execution of a program by the processor 1120 through an input device and check the processing result of the processor 1120 through an output device.

The communication interface 1150 may provide access to an external network.

An example of the present disclosure is directed to providing a method and apparatus for updating data efficiently according to the flying state of the apparatus, energy state of the apparatus and the type of data by utilizing an over the air (OTA) technique.

An example of the present disclosure is directed to providing a method and apparatus capable of preventing the difficulty of ensuring flying with updated information and shortening of a flying distance with the updated information if a designation is changed while flying.

According to an example of the present disclosure, a method for updating dynamic data and static data, the method comprising: receiving an update request; checking a flying state of an apparatus and a battery charging state of the apparatus; and updating at least one of the dynamic data or the static data indicating a situation change of the apparatus by using OTA (Over The Air) in consideration of the flying state and the battery charging state.

According to an example of the present disclosure, An apparatus for updating dynamic data and static data, the apparatus comprising: a memory comprising an instruction; and a processor for: receiving an update request by execution of the instruction; checking a flying state of an apparatus and a battery charging state of the apparatus; and updating at least one of the dynamic data or the static data indicating a situation change of the apparatus by using OTA (Over The Air) in consideration of the flying state and the battery charging state.

An example of the present disclosure can update data efficiently according to the flying state of the apparatus, energy state of the apparatus and the type of data by utilizing an OTA technique.

An example of the present disclosure can prevent the difficulty of ensuring flying with updated information and shortening of a flying distance with the updated information if a designation is changed while flying.

An example of the present disclosure can check a current battery state of the apparatus and update OTA selectively, thereby ensuring safe flying of the apparatus. The methods and apparatuses of the present disclosure have other features and advantages which will be apparent from or are set forth in more detail in the accompanying drawings, which are incorporated herein, and the following Detailed Description, which together serve to explain certain principles of the present disclosure.

At least some of the constituents described in the examples of the present disclosure may be implemented as hardware elements including at least one or a combination of a digital signal processor (DSP), a processor, a controller, an application specific integrated circuit (ASIC), a programmable logic device (such as FPGA, etc.), and other electronic devices. In addition, at least some of the functions or processes described in the examples may be implemented in software, and the software may be stored in a recording medium. At least some of the constituents, functions, and processes described in the examples of the present disclosure may be implemented as a combination of hardware and software.

The method according to examples of the present disclosure may be written as a program executable on a computer, and may also be implemented in various recording media such as a magnetic storage medium, an optical readable medium, a digital storage medium, etc.

The implementations of the various technologies described herein may be implemented as digital electronic circuitry, or as computer hardware, firmware, software, or combinations thereof. The implementations may be implemented as a computer program product, in other words, a computer program tangibly embodied in an information carrier, for example, a machine-readable storage medium (computer-readable medium) or a radio signal, for processing by the operation of a data processing device, for example, a programmable processor, a computer, or a plurality of computers, or for controlling the operation thereof. A computer program, such as the computer program(s) described above, may be written in any form of programming language, including compiled or interpreted languages, and may be deployed in any form, including as a stand-alone program or as a module, component, subroutine, or other unit suitable for use in a computing environment. The computer program may be deployed to be processed on one computer or a plurality of computers at one site, or distributed across a plurality of sites and interconnected by a communications network.

Processors suitable for processing a computer program include, for example, both general-purpose and special-purpose microprocessors, and any one or more processors of any type of digital computer. In general, the processor will receive instructions and data from a read-only memory or a random access memory or both. Elements of the computer may include at least one processor for executing instructions and one or more memory devices for storing instructions and data. In general, a computer may include one or more mass storage devices for storing data, such as magnetic, magneto-optical disks, or optical disks, or may be coupled to receive data from, transmit data to, or both. Information carriers suitable for embodying computer program instructions and data include, by way of example, semiconductor memory devices, magnetic media such as hard disks, floppy disks, and magnetic tape, optical media such as CD-ROMs (Compact Disk Read Only Memory) and DVDs (Digital Video Disk), magneto-optical media such as floptical disks, ROMs (Read Only Memory), RAMs (Random Access Memory), flash memory, EPROMs (Erasable Programmable ROM), EEPROMs (Electrically Erasable Programmable ROM), etc. The processor and memory may be supplemented by, or included in, special purpose logic circuitry.

What is claimed is:

1. A method performed by an apparatus for controlling operation of a vehicle, the method comprising:
receiving an update request;
checking, based on the update request, a flying state of the vehicle and a battery charging state of the vehicle;
updating, based on the flying state, the battery charging state, and data received via over-the-air (OTA), at least one of dynamic data or static data, wherein the dynamic data indicates a change in operational conditions of the vehicle;
outputting, based on the updating the at least one of the dynamic data or the static data, a signal; and
controlling, based on the signal, the operation of the vehicle.

2. The method of claim 1, wherein the updating the at least one of the dynamic data or the static data comprises, based on the flying state corresponding to a pre-flight state and the battery charging state indicating an energy level of a battery of the vehicle being above a threshold level, updating the dynamic data and the static data, wherein the pre-flight state represents the vehicle receiving a request for flight but not yet deployed.

3. The method of claim 1, wherein the updating the at least one of the dynamic data or the static data comprises executing, based on a failure of the updating, a recovery mode, wherein the failure corresponds to updated data overlapping, conflicting, or colliding with existing data, and wherein the recovery mode corresponds to an operation of rechecking an update.

4. The method of claim 2, wherein the updating the at least one of the dynamic data or the static data further comprises, based on the flying state corresponding to an in-flight state and the battery charging state indicating the energy level of the battery being above the threshold level, updating the dynamic data, wherein the in-flight state represents the vehicle being airborne or actively flying.

5. The method of claim 2, further comprising:
based on the flying state corresponding to an in-flight state and the battery charging state indicating the energy level of the battery being below the threshold level, determining whether the battery is in a state capable of using a selective update mode, wherein the in-flight state represents the vehicle being airborne or actively flying;
determining, based on a determination that the battery is in the state capable of using the selective update mode, a priority of data to update; and
selectively updating, based on the determined priority of data, the dynamic data.

6. The method of claim 5, wherein the determining the priority of data comprises determining the priority of data to update such that a maximum flying distance is ensured based on the flying state of the vehicle.

7. The method of claim 5, further comprising, based on the battery being in a state not capable of using the selective update mode, guiding the vehicle to an alternative landing point.

8. The method of claim 5, wherein the selective updating the dynamic data comprises:
determining a failure of the updating the at least one of the dynamic data or the static data, wherein the failure is associated with data consistency between updated data and existing data; and
based on the determining the failure, re-executing an update process of the at least one of the dynamic data or the static data.

9. The method of claim 1, further comprising determining the battery charging state by comparing energy currently available in the vehicle with a sum of:
energy required for the vehicle to fly from a current location of the vehicle to a destination,
energy required for the vehicle to perform the updating, and
system energy required for the vehicle to perform system operations during the fly from the current location to the destination.

10. The method of claim 1, further comprising:
updating the static data in a read only memory (ROM) and a random access memory (RAM); and
updating the dynamic data in the RAM and a non-volatile memory (NVM).

11. An apparatus for controlling operation of a vehicle, the apparatus comprising:
a processor; and
a memory comprising an instruction that, when executed by the processor, is configured to cause the apparatus to:
receive an update request;
check, based on the update request, a flying state of the vehicle and a battery charging state of the vehicle;
update, based on the flying state, the battery charging state, and data received via over-the-air (OTA), at least one of dynamic data or static data, wherein the dynamic data indicates a change in operational conditions of the vehicle;
output, based on the updated at least one of the dynamic data or the static data, a signal; and
control, based on the signal, the operation of the vehicle.

12. The apparatus of claim 11, wherein the instruction, when executed by the processor, is configured to cause the apparatus to, based on the flying state corresponding to a pre-flight state and the battery charging state indicating an energy level of a battery of the vehicle being above a threshold level, update the dynamic data and the static data, wherein the pre-flight state represents the vehicle receiving a request for flight but not yet deployed.

13. The apparatus of claim 11, wherein the instruction, when executed by the processor, is configure to cause the apparatus to, based on a failure of the update, execute a recovery mode, wherein the failure corresponds to updated data overlapping, conflicting, or colliding with existing data, and wherein the recovery mode corresponds to an operation of rechecking an update.

14. The apparatus of claim 12, wherein the instruction, when executed by the processor, is further configured to cause the apparatus to update, based on the flying state corresponding to an in-flight state and the battery charging state indicating the energy level of the battery being above the threshold level, the dynamic data, wherein the in-flight state represents the vehicle being airborne or actively flying.

15. The apparatus of claim 12, wherein the instruction, when executed by the processor, is configured to cause the apparatus to:
based on the flying state corresponding to an in-flight state and the battery charging state indicating the energy level of the battery being below the threshold level, determine whether the battery is in a state capable of using a selective update mode, wherein the in-flight state represent the vehicle being airborne or actively flying;
determine, based on the battery being in the state capable of using the selective update mode, a priority of data to update; and
selectively update, based on the determined priority of data, the dynamic data.

16. The apparatus of claim 15, wherein the instruction, when executed by the processor, is configured to cause the apparatus to, based on the battery being in a state not capable of using the selective update mode, guide the vehicle to an alternative landing point.

17. The apparatus of claim 15, wherein the instruction, when executed by in the processor, is configured to cause the apparatus to:
determine a failure to update the at least one of the dynamic data or the static data, wherein the failure is associated with data consistency between updated data and existing data; and
based on the determined failure, re-execute an update process of the at least one of the dynamic data or the static data.

18. The apparatus of claim 11, wherein the instruction, when executed by the processor, is configured to cause the apparatus to determine the battery charging state by comparing energy currently available in the vehicle with a sum of:
energy required for the vehicle to fly from a current location of the vehicle to a destination,
energy required for the vehicle to update the at least one of the dynamic data or the static data, and
system energy required for the vehicle to perform system operations during the fly from the current location to the destination.

19. The apparatus of claim 11, wherein the instruction, when executed by the processor, is configured to cause the apparatus to:
update the static data in a read only memory (ROM) and a random access memory (RAM); and
update the dynamic data in the RAM and a non-volatile memory (NVM).

20. An apparatus for controlling operation of a vehicle, the apparatus comprising:
a processor; and
a memory comprising an instruction that, when executed by the processor, is configured to cause the apparatus to:
identify an update event indicating an update of first data and second data is available;
determine, based on the identified update event, a flying state of the vehicle and a battery charging state of the vehicle;
update, based on the flying state, the battery charging state, and a type of the first data corresponding to a first data type, the first data with third data received via over-the-air (OTA);
suspend, based on the flying state, the battery charging state, and the type of the second data corresponding to a second data type, update of the second data until a change of at least one of the flying state or the battery charging state; and
control, based on the updating of the first data with the third data, the operation of the vehicle.
